(19) United States
(12) Patent Application Publication
(10) Pub. No.: US 2017/0248650 A1
(43) Pub. Date: Aug. 31, 2017

(54) TESTING SYSTEM, DEVICE OF A DATA COLLECTING CHIP AND CONTROL METHOD THEREOF

(71) Applicant: SHENZHEN HUIDING TECHNOLOGY CO., LTD., Shenzhen (CN)

(72) Inventors: Weihe QIN, Shenzhen (CN); Zhou GUAN, Shenzhen (CN); Haihong SONG, Shenzhen (CN); Lian YANG, Shenzhen (CN)

(21) Appl. No.: 15/594,552

(22) Filed: May 12, 2017

Related U.S. Application Data
(63) Continuation of application No. PCT/CN2016/089414, filed on Jul. 8, 2016.

(30) Foreign Application Priority Data
Feb. 2, 2016 (CN) 201610074545.6

(51) Int. Cl. G01R 31/26; G01R 31/28

(52) U.S. Cl. CPC G01R 31/2646; G01R 31/2834; H04B 1/38

(57) ABSTRACT

A testing device of a data collecting chip (10) and control method thereof, and the testing device (10) includes: a data collecting module (200) for receiving multiple frames of sampling data sampling data collected by the data collecting chip; a storing module (300); a processing module (400) for calculating noise of a plurality of data sampling points to obtain a noise test result; a data transceiving module (500) for uploading the noise test result; and a control module (600). The testing device (10) only uploads the noise test result by calculating the noise of the plurality of data sampling points, so that the efficiency of a chip test is improved, the cost of the chip test is reduced, and the test reliability is ensured better.

### CROSS-REFERENCE TO RELATED APPLICATIONS

This application is a continuation of International Application No. PCT/CN2016/089414, filed on Jul. 8, 2016, which claims priority to Chinese Patent Application No. 201610074545.6, filed on Feb. 2, 2016. The disclosures of the aforementioned applications are hereby incorporated by reference in their entireties.

### TECHNICAL FIELD

The present disclosure relates to the field of fingerprint identification technologies, and in particular, testing system, device of a data collecting chip and control method thereof.

### BACKGROUND

In the related technologies, as shown in FIG. 1, a testing system for a fingerprint identification chip generally test a plurality of chips simultaneously, thereby improving the efficiency of the test. Since an ATE (Automatic Test Equipment, automatic test equipment) does not possess a calculation function, in the test, the ATE firstly collects test data of multiple pieces of DUTs (Device Under Test, device under test), and then uploads the test data of the multiple pieces of DUTs to a PC end to complete a noise calculation at the PC end for each piece of DUT. The noise calculation is generally to calculate a variance of position data of the same pixel in data of multiple frames.

However, in the foregoing system, since a data transmission mode between the ATE and the PC is a serial transmission, the data transmission takes a great deal of time once the amount of the data collected is large, and the test cost are increased greatly especially when a mass production test of the chip is carried out; merely using a mode of calculating the variance for the noise calculation, as shown in FIG. 2, the variance of the data does not reflect the noise level of the pixel point accurately once the noise appears as Jit, thereby affecting the stability of the fingerprint identification chip so as to reduce the accuracy of the fingerprint identification.

### SUMMARY

The present disclosure is designed to solve one of technical problems in the related technologies to a certain extent.

With respect to this, an objective of the present disclosure is to provide a testing device of a data collecting chip, the device may improve the efficiency of a chip test and reduce the cost of the chip test.

Another objective of the present disclosure is to provide a testing system of a data collecting chip.

A Further objective of the present disclosure is to provide a control method for a testing device of a data collecting chip.

To implement the foregoing objectives, one aspect of embodiments of the present disclosure provides a testing device of a data collecting chip, the data collecting chip includes a plurality of data sampling points, and the testing device includes: a data collecting module, the data collecting module being connected to the data collecting chip, and configured to receive multiple frames of sampling data collected by the data collecting chip; a storing module, the storing module being configured to store the multiple frames of sampling data; a processing module, the processing module being configured to calculate noise of the plurality of data sampling points according to the multiple frames of sampling data to obtain a noise test result; a data transceiving module, the data transceiving module being configured to upload the noise test result to an upper computer; and a control module, the control module being configured to control the data collecting module, the storing module, the processing module and the data transceiving module.

A testing device of a data collecting chip of embodiments of the present disclosure calculates noise of a plurality of data sampling points according to multiple frames of sampling data to obtain a noise test result by calculating the noise of the plurality of data sampling points, and upload the noise test result to an upper computer, so that the efficiency of a chip test is improved, the cost of the chip test is reduced, and the test reliability is ensured better.

In addition, according to the embodiments of the present disclosure, the testing device of the data collecting chip may further include the following additional technical features:

Optionally, in an embodiment of the present disclosure, the data collecting chip is a fingerprint identification chip.

Further, in an embodiment of the present disclosure, the storing module includes: a memory module, configured to store the multiple frames of sampling data; a memory control module, the memory control module being connected to the memory module and the control module respectively, to control the memory module to read or write the multiple frames of sampling data under the control of the control module.

Further, in an embodiment of the present disclosure, each frame sampling data in the multiple frames of sampling data includes sampling values of the plurality of data sampling points, and the processing module includes: a calculating unit module, the calculating unit module being connected to the control module to calculate a variance of a plurality of sampling values for each data sampling point in the multiple frames of sampling data and a bulge value of the plurality of sampling values for each data sampling point in the multiple frames of sampling data; a noise determining module, the noise determining module being connected to the calculating unit module, and configured to determine whether the variance corresponding to each data sampling point is less than a predetermined variance and whether the bulge value corresponding to the each data sampling point is less than a predetermined bulge value to determine whether a noise test of the each data sampling point passes, and then obtain the noise test result.

Further, in an embodiment of the present disclosure, the data collecting module has a cache for caching the multiple frames of sampling data.

Optionally, in an embodiment of the present disclosure, the testing device further includes a switch module, the switch module includes one or more switches, the number of the data collecting chip is one or more, and the one or more data collecting chips are connected to the one or more switches one to one; the data collecting module receives the multiple frames of sampling data collected by the data collecting chip after the switch module is closed.

To implement the foregoing objectives, another aspect of embodiments of the present disclosure provides a testing system of a data collecting chip, including: the testing device of the data collecting chip according to the foregoing description; an automatic test equipment ATE, the ATE being connected to the testing device of the data collecting chip; and a PC, the PC being connected to the ATE, the PC obtaining a noise test result uploaded by the testing device of the data collecting chip via the ATE, and then performing corresponding operations on the data collecting chip according to the noise test result.

A testing system of a data collecting chip of embodiments of the present disclosure, the testing devices calculates noise of a plurality of data sampling points according to multiple frames of sampling data to obtain a noise test result by calculating the noise of the plurality of data sampling points, and then determine whether the data collecting chip is qualified, and upload the noise test result to an upper computer, so that the efficiency of a chip test is improved, the cost of the chip test is reduced, and the test reliability is ensured better.

To implement the foregoing objectives, still another aspect of embodiments of the present disclosure provides a control method for a testing device of a data collecting chip, including the following steps: receiving multiple frames of sampling data collected by the data collecting chip, and storing the multiple frames of sampling data; calculating noise of a plurality of data sampling points according to the multiple frames of sampling data to obtain a noise test result; and uploading the noise test result to an upper computer.

A control method for a testing device of a data collecting chip of embodiments of the present disclosure calculates noise of a plurality of data sampling points according to multiple frames of sampling data to obtain a noise test result by calculating the noise of the plurality of data sampling points, and upload the noise test result to an upper computer, so that the efficiency of a chip test is improved, the cost of the chip test is reduced, and the test reliability is ensured better.

In addition, according to the embodiments of the present disclosure, the control method for the testing device of the data collecting chip may further include the following additional technical features:

Further, in an embodiment of the present disclosure, each frame sampling data in the multiple frames of sampling data includes sampling values of the plurality of data sampling points, and the calculating the noise of the plurality of data sampling points according to the multiple frames of sampling data to obtain the noise test result further includes: calculating a variance of a plurality of sampling values for each data sampling point in the multiple frames of sampling data and a bulge value of the plurality of sampling values for each data sampling point in the multiple frames of sampling data; determining whether the variance corresponding to each data sampling point is less than a predetermined variance and whether the bulge value corresponding to the each data sampling point is less than a predetermined bulge value to determine whether a noise test of the each data sampling point passes, and then obtain the noise test result.

Further, in an embodiment of the present disclosure, after the receiving the multiple frames of sampling data collected by the data collecting chip, the foregoing method further includes: caching the multiple frames of sampling data.

Additional aspects and advantages of the present disclosure will be partly provided in the following description, and part of them will be obvious from the following description, or may be understood by practice of the present disclosure.

### BRIEF DESCRIPTION OF DRAWINGS

The foregoing and/or additional aspects and advantages of the present disclosure will be clear and better understood from the following description of embodiments by combining with drawings, in which:

FIG. 1 is schematic diagram of a structure of a testing system for a chip of fingerprint identification type in a related technology;

FIG. 2 is a schematic diagram of Jit noise in a related technology;

FIG. 3 is a schematic diagram of a pixel matrix in a fingerprint identification chip;

FIG. 4 is a schematic diagram of noise of a pixel point;

FIG. 5 is a schematic diagram of a structure of a testing device of a data collecting chip according to embodiments of the present disclosure;

FIG. 6 is a schematic diagram of a structure of a testing device of a data collecting chip according to a specific embodiment of the present disclosure;

FIG. 7 is a flowchart diagram of a control method for a testing device of a data collecting chip according to embodiments of the present disclosure; and

FIG. 8 is a flowchart diagram of a control method for a testing device of a data collecting chip according to a specific embodiment of the present disclosure.

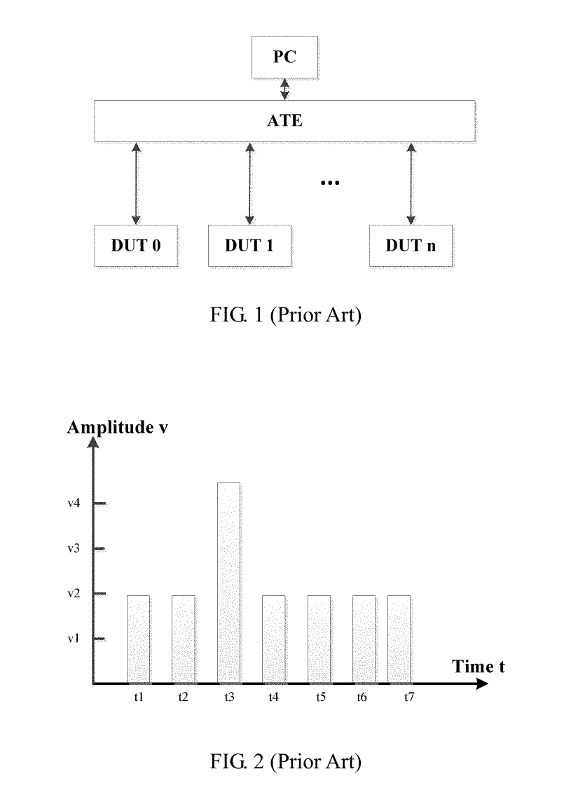

### DESCRIPTION OF EMBODIMENTS

Embodiments of the present disclosure are described as follows in detail, and examples of the embodiments are illustrated in drawings, in which the same or similar labels are throughout indicative of the same or similar elements or elements with the same or similar functions. The embodiments described below with reference to the drawings are exemplary, are designed to explain the present disclosure, and are not understood as a limit on the present disclosure.

Prior to describing a testing system, device of a data collecting chip and control method for the testing device of the data collecting chip provided according to embodiments of the present disclosure, firstly, the importance of a chip test is briefly described as follows.

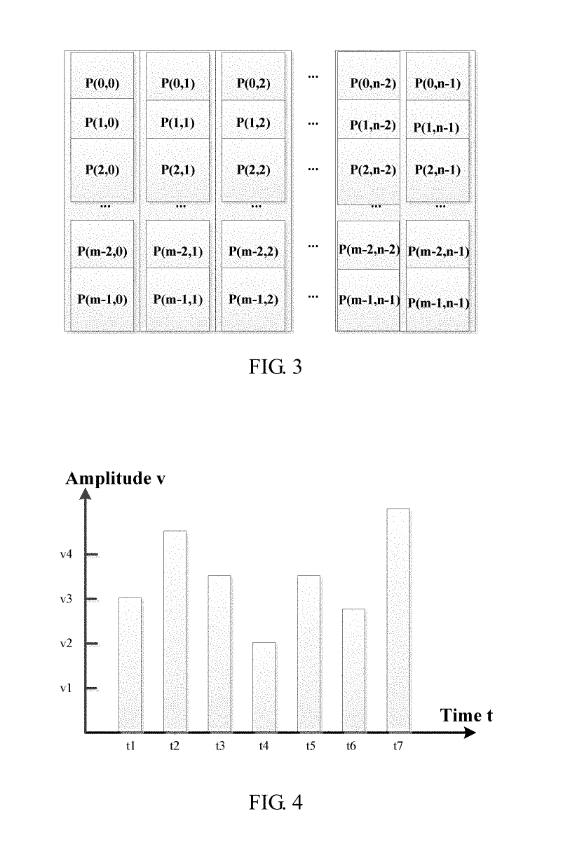

A fingerprint identification chip, for example, the stability of the fingerprint identification chip may affect the quality of a collected fingerprint image and the final accuracy of fingerprint identification. As shown in FIG. 3, m*n pixel points are on the surface of the fingerprint identification chip, and each pixel point has different noise due to differences of components in a circuit and the effect of system design; as shown in FIG. 4, the drawing shows data collected at the same pixel point at different moments in no-load state, and being affected by the noise, the amplitude of the collected data may fluctuate, the greater the noise the greater the fluctuation; the data collected at the pixel point would not be identified once the noise exceeds a certain range, and the fingerprint identification would fail when the number of pixel points that cannot be identified exceeds a certain number in am x n pixel matrix. The importance of the chip test can be known.

However, in the related technologies, a data transmission (serial transmission) between an ATE and a PC takes a great deal of time once the amount of data collected is large, the test cost is increased greatly, and since a variance of the data does not reflect the noise level of the pixel point accurately, the stability of the fingerprint identification chip is affected, and then the accuracy of fingerprint identification is reduced.

The present disclosure provides a testing system, device of a data collecting chip and control method for the testing device of the data collecting chip based on the foregoing problems.

The following describes the testing system, device of a data collecting chip and control method for the testing device of the data collecting chip provided according to embodiments of the present disclosure are described with reference to drawings. At first, the testing device of the data collecting chip provided according to the embodiments of the present disclosure is described with reference to the drawings as follows.

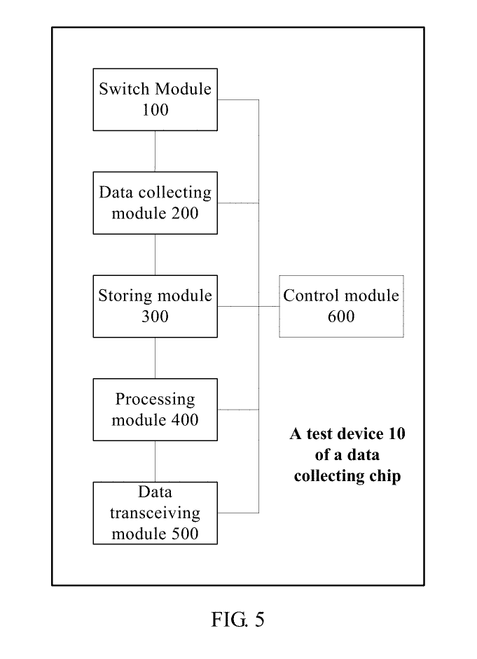

FIG. 5 is a schematic diagram of a structure of the testing device of the data collecting chip according to the embodiments of the present disclosure.

As shown in FIG. 5, the testing device 10 of the data collecting chip includes: a switch module 100, a data collecting module 200, a storing module 300, a processing module 400, a data transceiving module 500 and a control module 600.

The data collecting chip includes a plurality of data sampling points. Particularly, the data collecting module 200 is connected to the data collecting chip via the switch module 100, so that the data collecting module 200 receives multiple frames of sampling data collected by the data collecting chip after the switch module 100 is closed. The storing module 300 is configured to store the multiple frames of sampling data. The processing module 400 is configured to calculate noise of the plurality of data sampling points according to the multiple frames of sampling data to obtain a noise test result. The data transceiving module 500 is configured to upload the noise test result to an upper computer. The control module 600 is configured to control the switch module 100, the data collecting module 200, the storing module 300, the processing module 400 and the data transceiving module 500. The testing device 10 of the embodiments of the present disclosure has a noise calculation capability of a PC, and merely uploads the noise test result to the upper computer according to the calculation of the sampling data, and thus the amount of data transmission between the data collecting chip and the upper computer is reduced, such that the efficiency and accuracy of a chip test are improved, the cost of the chip test is reduced, and the test reliability is ensured better.

Optionally, in an embodiment of the present disclosure, the data collecting chip may be a fingerprint identification chip, so that the test cost of the fingerprint identification chip is reduced greatly, the stability of the fingerprint identification chip is ensured, and then the accuracy of fingerprint identification is improved.

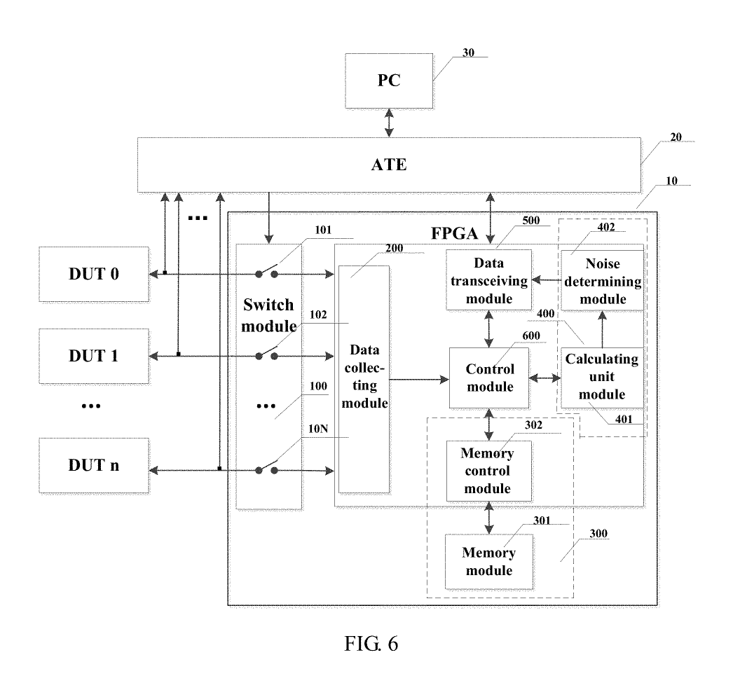

Further, in an embodiment of the present disclosure, as shown in FIG. 6, the upper computer of the embodiment of the present disclosure includes: an ATE 20 and a PC 30. The ATE 20 is connected to the testing device, and the PC 30 is connected to the ATE 20.

The data collecting chip (i.e., the chip under test), the ATE and the testing device 10 of the embodiments of the present disclosure may communicate with each other independently; however, the chip under test and the device of the present disclosure are separated by the switch module 100 (equivalent to an analog switch), thereby avoiding the influence of testing device 10 of the embodiments of the present disclosure when the ATE tests other test items of a DUT; the testing device 10 of the embodiments of the present disclosure collects, converts and stores the data in a local mass memory to ensure the stability of the test after the switch module is closed.

Further, in an embodiment of the present disclosure, as shown in FIG. 6, the storing module 300 includes: a memory module 301 and a memory control module 302.

The memory module 301 is configured to store the multiple frames of sampling data. The memory control module 302 is connected to the memory module 301 and the control module 600 respectively, to control the memory module 301 to read or write the multiple frames of sampling data under the control of the control module 600.

Further, in an embodiment of the present disclosure, the data collecting module 200 has a cache (not specifically identified in the drawing) for caching the multiple frames of sampling data.

Optionally, in an embodiment of the present disclosure, as shown in FIG. 6, the switch module 100 includes one or more switches (switch 101, switch 102 . . . switch 10N as shown in FIG. 6), the number of the data collecting chip is one or more (DUT 0, DUT 1 . . . DUT n), and the one or more data collecting chips are connected to the one or more switches one to one.

Further, in an embodiment of the present disclosure, as shown in FIG. 6, the processing module 400 includes: a calculating unit module 401 and a noise determining module 402.

Each frame sampling data in the multiple frames of sampling data includes sampling values of the plurality of data sampling points. Particularly, the calculating unit module 401 is connected to the control module 600 to calculate a variance of a plurality of sampling values for each data sampling point in the multiple frames of sampling data and a bulge value of the plurality of sampling values for each data sampling point in the multiple frames of sampling data. The noise determining module 402 is connected to the calculating unit module 401, and the noise determining module 402 is configured to determine whether the variance corresponding to each data sampling point is less than a predetermined variance and whether the bulge value corresponding to the each data sampling point is less than a predetermined bulge value to determine whether a noise test of the each data sampling point passes, and then obtain the noise test result of the data collecting chip. For example, the number of the data sampling points whose variance is greater than the predetermined variance, or whose bulge value is greater than the predetermined bulge value, or whose variance is greater than the predetermined variance and whose bulge value is greater than the predetermined bulge value is recorded; if the number is greater than a predetermined number, the noise test of the corresponding data collecting chip passes, otherwise it does not pass.

It is to be noted that the predetermined variance, the predetermined bulge value and the predetermined number may be adjusted according to actual conditions.

In the embodiments of the present disclosure, the testing device 10 of the embodiments of the present disclosure performs the noise test by calculating the variance and the bulge value of the sampling values of the same pixel point at different moments, and the noise test result, for example, the noise test of the data collecting chip passes or does not pass, is uploaded to the upper computer, such as the ATE 20.

In a specific embodiment of the present disclosure, as shown in FIG. 6, the data collecting module 200, the storing module 300, the processing module 400, the data transceiving module 500 and the control module 600 may be implemented via FPGA (Field-Programmable Gate Array). The switch module 100 is responsible for controlling whether a data transmission bus between the DUT and the FPGA is conducting, and the DUT may communicate with the ATE 20 when the switch module 100 is open; the DUT communicates with the FPGA when the switch module 100 is closed. The data collecting module 200 is primarily responsible for collecting data of the DUT, that is, receiving the multiple frames of sampling data collected by the data collecting chip, then, the multiple frames of sampling data is sent to the cache after being performed a corresponding conversion, and a request signal is generated and output to a lower module when the cached data reaches a certain amount. The control module 600 is primarily responsible for controlling the whole system, such as triggering the data collecting module 200 to collect the data and receive a read cache request signal, triggering the memory control module 302 to start the memory module 301 to read or write the data, and the like. The memory control module 302 is primarily responsible for controlling the memory module 301 and arbitrating the read or write of the data. The memory module 301 is primarily responsible for storing a great deal of data of the DUT. The calculating unit module 401 is primarily responsible for completing the implementation of noise test algorithm, and outputting a result. The noise determining module 402 is primarily responsible for determining the result output by the calculating unit module 401, and determining whether the test passes. The data transceiving module 500 is primarily responsible for receiving the data sent by the ATE 20 to the FPGA and sending the noise test result to the ATE 20.

For example, the switch in the switch module 100 is closed after the ATE 20 configures the DUT and the FPGA, and the data enters the data collecting module 200 via the switch module 100; data collation is completed in the data collecting module 200, including serial-to-parallel conversion, the control module 600 is triggered after processing the cache and the like, and the control module 600 starts the memory control module 302, the memory control module 302 sequentially writing the data cached by the upper module into the memory module 301; the control module 600 starts the memory control module 302 to fetch the data from the memory module 301 to the calculating unit module 401 after storing data of N frames, the noise calculation is completed in the calculating unit module 401 and the result is sent to the noise determining module 402; a comparison according to a noise calculating result and a predetermined threshold value is implemented at the noise determining module 40 to determine whether the test of the data sampling point passes, and then the noise test result is sent to the data transceiving module 500, and sent to the PC via the ATE 20 after being analyzed; the PC classifies the DUT according to the received noise test result, for example, the noise test of the DUT 0 does not pass or pass, and the DUT whose noise test result does not pass will be discarded.

It is to be noted that how to use the variance and Jit calculation will be described in detail in the following embodiments of a control method for a testing device of a data collecting chip.

According to a testing device of a data collecting chip of embodiments of the present disclosure, after a switch module is closed, noise of a plurality of data sampling points is calculated according to multiple frames of sampling data to obtain a noise test result by calculating the noise of the plurality of data sampling points, and thus the noise test result is uploaded to an upper computer, so that the test time is reduced, and the efficiency of a chip test is improved; and a noise calculation is completed through the calculation of a variance and a bulge value, so that the accuracy of the chip test is improved, the cost of the chip test is reduced, and the test reliability is ensured better.

Embodiment of the present disclosure further provides a testing system of a data collecting chip, and the system includes the foregoing testing device of the data collecting chip, the ATE and the PC. The ATE is connected to the testing device of the data collecting chip, the PC is connected to the ATE, and the PC obtains a noise test result uploaded by the testing device of the data collecting chip via the ATE, and then performs corresponding operations on the data collecting chip according to the noise test result.

It is to be understood that the specific implementation procedure according to of the testing system of the data collecting chip of the embodiments of the present disclosure is the same as described in the testing device of the data collecting chip of the embodiments of the present disclosure, and will not be described in detail herein.

According to a testing system of a data collecting chip of embodiments of the present disclosure, a testing device calculates noise of a plurality of data sampling points according to multiple frames of sampling data to determine whether the data collecting chip is qualified by calculating the noise of the plurality of data sampling points, and then upload a noise test result to a PC via an ATE, so that the test time is reduced, and the efficiency of a chip test is improved, and a noise calculation is completed through the calculation of a variance and a bulge value, so that the accuracy of the chip test is improved, the cost of the chip test is reduced, and the test reliability is ensured better.

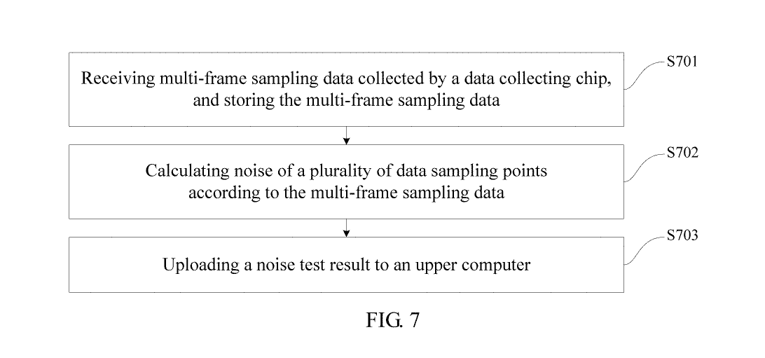

FIG. 7 is a flowchart diagram of a control method for a testing device of a data collecting chip according to embodiments of the present disclosure.

As shown in FIG. 7, the control method for the testing device of the data collecting chip (including a plurality of data sampling points) includes the following steps:

S701: receiving multiple frames of sampling data collected by the data collecting chip, and storing the multiple frames of sampling data.

In an embodiment of the present disclosure, after receiving the multiple frames of sampling data collected by the data collecting chip, the control method of the embodiments of the present disclosure further includes: caching the multiple frames of sampling data.

S702: calculating noise of the plurality of data sampling points according to the multiple frames of sampling data to obtain a noise test result.

In an embodiment of the present disclosure, each frame sampling data in the multiple frames of sampling data includes sampling values of the plurality of data sampling points, and the calculating the noise of the plurality of data sampling points according to the multiple frames of sampling data to obtain the noise test result further includes: calculating a variance of a plurality of sampling values for each data sampling point in the multiple frames of sampling data and a bulge value of the plurality of sampling values for each data sampling point in the multiple frames of sampling data; determining whether the variance corresponding to each data sampling point is less than a predetermined variance and whether the bulge value corresponding to the each data sampling point is less than a predetermined bulge value to determine whether a noise test of the each data sampling point passes, and then obtain the noise test result.

S703: uploading the noise test result to an upper computer.

It is to be noted that the forgoing explanation to the embodiments of the testing device of the data collecting chip is further applicable to the control method for the testing device of the data collecting chip of the embodiments, and the description thereof will not be described redundantly herein.

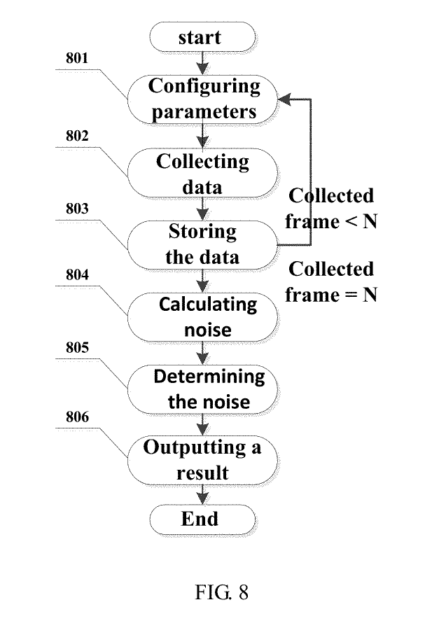

A specific embodiment of the present disclosure describes how to use the variance and Jit calculation in detail; as shown in FIG. 8, a control method of embodiments of the present disclosure includes the following steps:

S801: configuring parameters.

It is to be understood that an ATE disconnects a switch in a switch module firstly, and controls a DUT and a FPGA to operate under a specific mode by issuing configuration parameters.

The configuration of the DUT includes setting a scan mode, ADC amplitude, integration times and the like, and the DUT enters a waiting scanning state; the configuration of the FPGA includes setting pixel specification (m*n matrix), collecting data bit width, collecting data frame number of the current DUT and the like, and the FPGA finally enters a waiting collecting state.

S802: collecting data.

That is, after the ATE completes the configuration of the parameters of the DUT and the FPGA, the switch in the switch module is closed, and the DUT and the FPGA are triggered to enter a data collecting mode. A data bus connected between the DUT and the FPGA is usually a serial bus, such as SPI, I²C bus, or the like; therefore, the collected data needs to perform serial-to-parallel conversion firstly after entering the FPGA, then is stored in a cache according to a specific format, and the cache is usually implemented using FIFO. According to the parameters configured by the ATE, a request signal may be sent out when the cached data reaches a configuration number, requesting a lower module to read the data in the cache.

S803: storing the data.

Further, a memory control module is triggered when a control module receives the request signal to read the cached data in a collecting data module and write it in a memory module, where a memory is usually an external memory, such as SDRAM, SPAM or the like. Since the data collecting is to collect multiple DUTs in parallel, it is necessary to arbitrate the data in the memory control module, and the data of each DUT is written in the memory module one by one until the data of N (setting a value of N according to design requirements, N is greater than or equivalent to 2) frames are stored.

S804: calculating noise.

For example, after the data of N frames are collected, the control module triggers the memory control module to fetch the data to a calculating unit module in a specified format, and then the noise calculation for each pixel point is completed in the calculating unit module. The noise calculation includes two parts, where a first part is to calculate a variance S² of the data of the same pixel point in data of multiple frames, which can be expressed as:

S²=((x1−M)²+(x2−M)²)/n,

wherein x1, x2, . . . xn correspond to data of a first, second, . . . Nth frame of the pixel respectively, and M is an average value of the data of N frames of the pixel point;

A second part is to calculate a bulge value V of the data of the same pixel point in the data of multiple frames, which can be expressed as:

V=max(x1, x2, . . . , xn)−min(x1, x2, . . . , xn).

S805: determining the noise.

The determination of the noise may be divided into two items:

One is to determine whether the variance S² and the Jit V of each pixel point are less than threshold values of a LimVar and a LimJit; if both are less than the corresponding threshold values, it is determined that a noise test on the pixel point passes; otherwise, it fails, and a counter FailNum is added by 1:

s²≧LimVar or V≧LimJit:fail; FailNum++;

s²<LimVar and V<LimJit:pass;

A second is whether the number of pixels failed in the noise test in a pixel matrix is greater than a threshold value LimNum; if it is less than the threshold value LimNum, it is determined that a DUT noise test corresponding to the pixel matrix passes, otherwise it fails.

FailNum≧LimNum:fail;

FailNum<LimNum:pass.

S806: outputting a result.

That is, a noise determining module sends a noise test result in a data transceiving module, and then the data transceiving module uploads the result to the ATE according to an interface protocol.

According to a control method for a testing device of a data collecting chip of embodiments of the present disclosure, noise of a plurality of data sampling points is calculated according to multiple frames of sampling data to obtain a noise test result by calculating the noise of the plurality of data sampling points, and thus the noise test result is uploaded to an upper computer, so that the test time is reduced, and the efficiency of a chip test is improved; noise calculation is completed through the calculation of a variance and a bulge value, so that the accuracy of the chip test is improved, the cost of the chip test is reduced, and the test reliability is ensured better.

In the description of the present disclosure, it is to be understood that orientation or the positional relationship indicated by terms, such as “center”, “vertical”, “horizontal”, “length”, “width”, “thickness”, “up”, “down”, “front”, “back”, “left”, “right”, “transverse”, “longitudinal”, “top”, “bottom”, “internal”, “external”, “clockwise”, “anticlockwise”, “axial”, “radial”, “circumferential”, is orientation or the positional relationship illustrated based on the drawings, which facilitates to describe the present disclosure and simplify the description, rather than indicates or implies that a device or element referred to must be of a specific orientation, constructed or operated in specific orientation; therefore, it cannot be understood as a limit on the present disclosure.

In addition, terms “first” and “second” are merely used for the description of objectives, and are not understood as indicating or implying the relative importance, or implicitly showing the number of technical features indicated. Thus, the features defined with “first” or “second” may include at least one feature, either explicitly or implicitly. In the description of the present disclosure, “a plurality of”, “more” and “multiple” means at least two, such as two, three, or the like, unless there is a clear and specific definition.

In the present disclosure, unless there is a clear provision and definition, terms, such as “install”, “connect”, “link”, “fix”, should be broadly understood, for example, it may be a fixed connection, a detachable connection, or into one; it may be a mechanical connection, or an electrical connection; it may be a direct connection, or an indirect connection via an intermediate medium; it may be an internal connection between two elements or the interactive relationship of two elements, unless there is a clear definition. Those ordinary skilled in the art may appreciate the specific meaning of the foregoing terms in the present disclosure according to specific conditions.

In the present disclosure, that a first feature is “above” or “under” a second feature may be a direct contact of the first and second features, or an indirect contact of the first and second features via an intermediate medium. Moreover, that the first feature is “on”, “above” and “over” the second feature may be that the first feature is directly above or obliquely above the second feature, or merely indicates that the level height of the first feature is higher than that of the second feature. That the first feature is “under”, “below” and “below” the second feature may be that the first feature is directly below or obliquely below the second feature, or merely indicates that the level height of the first feature is lower than that of the second feature.

In the description of the present disclosure, the description of reference terms, such as “an embodiment”, “some embodiments”, “example”, “specific example” or “some examples”, means that the specific features, structures, materials or characteristics described in combination with the embodiment or example are included in at least one embodiment or example of the present disclosure. In the specification, the schematic expression to the foregoing terms need not be for the same embodiment or example. Moreover, the specific features, structures, materials or characteristics described may be combined in any one or more embodiments or examples in an appropriate mode. In addition, those skilled in the art may combine different embodiments or examples and features of different embodiments or examples described in the specification when there is non-contradictory.

Although the embodiments of the present disclosure have been shown and described above, it is to be understood that the foregoing embodiments are exemplary, which cannot be understood as a limit on the present disclosure, and those ordinary skilled in the art may change, amend, substitute or transform the foregoing embodiments within the scope of the present disclosure.

What is claimed is:

1. A testing device of a data collecting chip, wherein the data collecting chip comprises a plurality of data sampling points, and the testing device comprises:
a data collecting module being connected to the data collecting chip, and configured to receive multiple frames of sampling data collected by the data collecting chip;
a storing module being configured to store the multiple frames of sampling data;
a processing module being configured to calculate noise of the plurality of data sampling points according to the multiple frames of sampling data to obtain a noise test result;
a data transceiving module being configured to upload the noise test result to an upper computer; and
a control module being configured to control the data collecting module, the storing module, the processing module and the data transceiving module.

2. The testing device of the data collecting chip according to claim 1, wherein the data collecting chip is a fingerprint identification chip.

3. The testing device of the data collecting chip according to claim 1, wherein the storing module comprises:
a memory module, configured to store the multiple frames of sampling data;
a memory control module being connected to the memory module and the control module respectively, to control the memory module to read or write the multiple frames of sampling data under the control of the control module.

4. The testing device of the data collecting chip according to claim 1, wherein each frame sampling data in the multiple frames of sampling data comprises sampling values of the plurality of data sampling points, and
the processing module comprises:
a calculating unit module being connected to the control module to calculate a variance of a plurality of sampling values for each data sampling point in the multiple frames of sampling data and a bulge value of the plurality of sampling values for each data sampling point in the multiple frames of sampling data; and
a noise determining module being connected to the calculating unit module, and configured to determine whether the variance corresponding to each data sampling point is less than a predetermined variance and whether the bulge value corresponding to the each data sampling point is less than a predetermined bulge value to determine whether a noise test of the each data sampling point passes, and then obtain the noise test result.

5. The testing device of the data collecting chip according to claim 1, wherein the data collecting module comprises a cache for caching the multiple frames of sampling data.

6. The testing device of the data collecting chip according to claim 1, further comprises a switch module, wherein
the switch module comprises one or more switches, the number of the data collecting chip is one or more, and the one or more data collecting chips are connected to the one or more switches one to one;
the data collecting module receives the multiple frames of sampling data collected by the data collecting chip after the switch module is closed.

7. A testing system of a data collecting chip, comprising:
a testing device of the data collecting chip, the testing device comprises:
a data collecting module being connected to the data collecting chip, and configured to receive multi-frame sampling data collected by the data collecting chip;
a storing module being configured to store the multiple frames of sampling data;
a processing module being configured to calculate noise of the plurality of data sampling points according to the multiple frames of sampling data to obtain a noise test result;
a data transceiving module being configured to upload the noise test result to an upper computer; and
a control module being configured to control the data collecting module, the storing module, the processing module and the data transceiving module;
an automatic test equipment (ATE) being connected to the testing device of the data collecting chip; and
a personal computer (PC) being connected to the ATE, the PC obtaining a noise test result uploaded by the testing device of the data collecting chip via the ATE, and then performing corresponding operations on the data collecting chip according to the noise test result.

8. A control method for a testing device of a data collecting chip, wherein the data collecting chip comprises a plurality of data sampling points, the control method comprises:
receiving multiple frames of sampling data collected by the data collecting chip, and storing the multiple frames of sampling data;
calculating noise of the plurality of data sampling points according to the multiple frames of sampling data to obtain a noise test result; and
uploading the noise test result to an upper computer.

9. The control method for the testing device of the data collecting chip according to claim 8, wherein each frame sampling data in the multiple frames of sampling data comprises sampling values of the plurality of data sampling points, and the calculating the noise of the plurality of data sampling points according to the multiple frames of sampling data to obtain the noise test result further comprises:
calculating a variance of a plurality of sampling values for each data sampling point in the multiple frames of sampling data and a bulge value of the plurality of sampling values for each data sampling point in the multiple frames of sampling data;
determining whether the variance corresponding to each data sampling point is less than a predetermined variance and whether the bulge value corresponding to the each data sampling point is less than a predetermined bulge value to determine whether a noise test of the each data sampling point passes, and then obtain the noise test result.

10. The control method for the testing device of the data collecting chip according to claim 8, after the receiving the multiple frames of sampling data collected by the data collecting chip, further comprising:
caching the multiple frames of sampling data.
